(19) United States
(12) Patent Application Publication
(10) Pub. No.: US 2013/0122688 A1
(43) Pub. Date: May 16, 2013

(54) PRESSURE-SENSITIVE ADHESIVE SHEET FOR DICING AND METHOD OF MANUFACTURING SEMICONDUCTOR DEVICE USING PRESSURE-SENSITIVE ADHESIVE SHEET FOR DICING

(71) Applicants: Takatoshi Sasaki, Ibaraki-shi (JP); Koji Mizuno, Ibaraki-shi (JP); Fumiteru Asai, Ibaraki-shi (JP); Goji Shiga, Ibaraki-shi (JP)

(72) Inventors: Takatoshi Sasaki, Ibaraki-shi (JP); Koji Mizuno, Ibaraki-shi (JP); Fumiteru Asai, Ibaraki-shi (JP); Goji Shiga, Ibaraki-shi (JP)

(73) Assignee: NITTO DENKO CORPORATION, Ibaraki-shi, Osaka (JP)

(21) Appl. No.: 13/811,570

(22) PCT Filed: Jul. 2, 2012
(86) PCT No.: PCT/JP2012/066890

§ 371 Date: Jan. 22, 2013

(30) Foreign Application Priority Data
Nov. 7, 2011 (JP) 2011-152769

(51) Int. Cl. H01L 21/78

(52) U.S. Cl. CPC H01L 21/78
USPC 438/463; 428/343; 428/354

(57) ABSTRACT

An object of the present invention is to provide a pressure-sensitive adhesive sheet for dicing that is capable of preventing scratching of an adsorption stage when laser-scribing a semiconductor wafer. Provided is a pressure-sensitive adhesive sheet for dicing having a base and a pressure-sensitive adhesive layer provided on the base, in which 0.02 to 5 parts by weight of an ultraviolet absorber is contained in the pressure-sensitive adhesive layer with respect to 100 parts by weight of resin solid content, and in which the light transmittance at a wavelength of 355 nm of the pressure-sensitive adhesive sheet for dicing is 30% to 80%.

### TECHNICAL FIELD

The present invention relates to a pressure-sensitive adhesive sheet for dicing. More particularly, the present invention relates to a pressure-sensitive adhesive sheet for dicing that is used in a method of manufacturing a semiconductor device having a laser scribing step. The present invention also relates to a method of manufacturing a semiconductor device using the pressure-sensitive adhesive sheet for dicing.

### BACKGROUND ART

Conventionally, there is a method of manufacturing a semiconductor chip, a so-called laser dicing method, in which a laser dicing sheet is applied to a semiconductor wafer, and the semiconductor wafer is irradiated with a laser beam to make the semiconductor wafer into individual pieces (for example, refer to Patent Documents 1 and 2). In the method of manufacturing a semiconductor chip described in Patent Document 1, a laser dicing sheet is applied to a semiconductor wafer, and the semiconductor wafer is processed in a condition that the laser dicing sheet is adsorbed by an adsorption stage. In the method of manufacturing a semiconductor chip described in Patent Document 2, the surface of the semiconductor wafer where the laser dicing sheet is applied is irradiated with a laser beam.

Because the distance between circuits becomes closer as the circuit pattern that is formed on the semiconductor chip becomes finer, the capacitance between the adjacent circuits increases. Along with this, a phenomenon occurs that a signal that is transmitted in the circuits is delayed (signal delay). Then, it has been proposed that a low dielectric material layer is formed on the circuits using a material with a low dielectric constant, a so-called low-k material (a low dielectric material), to lower the capacitance between the circuits.

Examples of the low dielectric material layer include a SiO₂ film (dielectric constant k=4.2), a SiOF film (k=3.5 to 3.7), and a SiOC film (k=2.5 to 2.8). Such low dielectric material layers can be formed on a semiconductor wafer by a plasma CVD method.

However, the low dielectric material layer is very brittle, and cracks are generated in the dicing step, which may cause an abnormal operation of the semiconductor element. Because of that, in recent years, an approach has been taken in which the low dielectric material layer is removed using a laser (laser scribing) and then dicing is performed with a blade or the like (for example, refer to Patent Document 3).

### PRIOR ART DOCUMENTS

### Patent Documents

Patent Document 1: JP-A-2010-56329
Patent Document 2: JP-A-2010-73897
Patent Document 3: JP-A-2010-093273

### SUMMARY OF THE INVENTION

### Problems to be Solved by the Invention

However, there is a problem in the method of manufacturing a semiconductor chip described in Patent Document 1 that the adsorption stage may be scratched due to the laser beam especially when an edge of the semiconductor wafer is processed, because the semiconductor wafer is processed in a condition that the laser dicing sheet is adsorbed by an adsorption stage. In addition, there is a problem in the method of manufacturing a semiconductor chip described in Patent Document 2 that the laser beam with high intensity reaches especially behind the portion where the semiconductor wafer is not applied, because the laser beam transmits into the laser dicing sheet with high transmittance. Also, there is a problem in the laser scribing step disclosed in Patent Document 3 that the adsorption stage may be scratched due to the laser beam especially when the edge of the semiconductor wafer is processed, in the same way as in the laser dicing disclosed in Patent Document 1, etc.

The present invention was made in view of the above-described problems, and an object thereof is to provide a pressure-sensitive adhesive sheet for dicing that is capable of preventing scratching of an adsorption stage when laser-scribing a semiconductor wafer, and a method of manufacturing a semiconductor device using the pressure-sensitive adhesive sheet for dicing.

### Means for Solving the Problems

As a result of investigation to solve the conventional problems, the present inventors found that scratching of the adsorption stage by a laser beam can be prevented by making a pressure-sensitive adhesive layer that configures the pressure-sensitive adhesive sheet for dicing contain a prescribed amount of an ultraviolet absorber to make the light transmittance at a wavelength of 355 nm of the pressure-sensitive adhesive sheet for dicing be within a prescribed range, and completed the present invention.

The pressure-sensitive adhesive sheet for dicing according to the present invention is a pressure-sensitive adhesive sheet for dicing having a base and a pressure-sensitive adhesive layer provided on the base, wherein 0.02 to 5 parts by weight of an ultraviolet absorber is contained in the pressure-sensitive adhesive layer with respect to 100 parts by weight of resin solid content, and the light transmittance at a wavelength of 355 nm of the pressure-sensitive adhesive sheet for dicing is 30% to 80%.

According to the above-described configuration, 0.02 to 5 parts by weight of an ultraviolet absorber is contained in the pressure-sensitive adhesive layer with respect to 100 parts by weight of the resin solid content, and the light transmittance at a wavelength of 355 nm of the pressure-sensitive adhesive sheet for dicing is 30% to 80%. Because the content of the ultraviolet absorber in the pressure-sensitive adhesive layer is 0.02 part by weight or more with respect to 100 parts by weight of the resin solid content, and the light transmittance at a wavelength of 355 nm of the pressure-sensitive adhesive sheet for dicing is 80% or less, the laser beam is absorbed by the pressure-sensitive adhesive layer and the amount of the laser beam that reaches the adsorption stage can be decreased when the low dielectric material layer formed on the semiconductor wafer is cut by light absorption ablation of the laser beam. As a result, scratching of the adsorption stage can be prevented. Because the content of the ultraviolet absorber in the pressure-sensitive adhesive layer is 5 parts by weight or less with respect to 100 parts by weight of the resin solid content, and the light transmittance at a wavelength of 355 nm of the pressure-sensitive adhesive sheet for dicing is 30% or more, melting of a tape can be prevented at laser absorption.

In the above-described configuration, the light transmittance at a wavelength of 355 nm of the base is preferably 70% to 100%. When the light transmittance at a wavelength of 355 nm of the base is 70% to 100%, the absorption of the laser beam at the base is relatively small, and damage to the base is small. As a result, tearing of the pressure-sensitive adhesive sheet for dicing can be prevented upon dicing and expanding.

In the above-described configuration, the base is preferably multi-layered. When the base is multi-layered, the intensity of laser can be weakened by light scattering between the layers and/or light refraction between the layers.

In the above-described configuration, the specific heat of the base is preferably 1.0 J/gK to 3.0 J/gK. When the specific heat of the base is 1.0 J/gK to 3.0 J/gK, generation of heat by laser absorption can be suppressed. In the case where the base is multi-layered, the specific heat of the base being 1.0 J/gK to 3.0 J/gK means that all of the specific heats of layers constituting the base is within a range of 1.0 J/gK to 3.0 J/gK.

In the above-described configuration, the melting point of the base is preferably 90° C. or more. When the melting point of the base is 90° C. or more, melting of the base by the heat at laser processing can be prevented.

The method of manufacturing a semiconductor device according to the present invention includes a step of applying the pressure-sensitive adhesive sheet for dicing to aback side of a semiconductor wafer in which a low dielectric material layer is formed on a front side; and a laser scribing step of irradiating the front side of the semiconductor wafer with an ultraviolet ray laser beam to cut the low dielectric material layer.

In the method of manufacturing a semiconductor device of the above-described configuration, a pressure-sensitive adhesive sheet for dicing is used in which 0.02 to 5 parts by weight of an ultraviolet absorber is contained in the pressure-sensitive adhesive layer with respect to 100 parts by weight of the resin solid content, and the light transmittance at a wavelength of 355 nm of the pressure-sensitive adhesive sheet for dicing is 30% to 80%. Because the content of the ultraviolet absorber in the pressure-sensitive adhesive layer is 0.02 part by weight or more with respect to 100 parts by weight of the resin solid content, and the light transmittance at a wavelength of 355 nm of the pressure-sensitive adhesive sheet for dicing is 80% or less, the laser beam is absorbed by the pressure-sensitive adhesive layer and the amount of the laser beam that reaches the adsorption stage can be decreased when the low dielectric material layer formed on the semiconductor wafer is cut by light absorption ablation of the laser beam. As a result, scratching of the adsorption stage can be prevented. Because the content of the ultraviolet absorber in the pressure-sensitive adhesive layer is 5 parts by weight or less with respect to 100 parts by weight of the resin solid content, and the light transmittance at a wavelength of 355 nm of the pressure-sensitive adhesive sheet for dicing is 30% or more, melting of a tape can be prevented at laser absorption.

### Effect of the Invention

According to the present invention, a pressure-sensitive adhesive sheet for dicing that is capable of preventing scratching of an adsorption stage by a laser beam and a method of manufacturing a semiconductor device using the pressure-sensitive adhesive sheet for dicing can be provided.

### BRIEF DESCRIPTION OF THE DRAWINGS

FIG. 1 is a cross-sectional schematic diagram showing one example of the pressure-sensitive adhesive sheet for dicing of the present invention.

FIGS. 2A and 2B are cross-sectional schematic diagrams showing one example of the method of manufacturing a semiconductor device using the pressure-sensitive adhesive sheet for dicing of the present invention.

FIGS. 3(a) and 3(b) are cross-sectional schematic diagrams showing one example of the method of manufacturing a semiconductor device using the pressure-sensitive adhesive sheet for dicing of the present invention.

### MODE FOR CARRYING OUT THE INVENTION

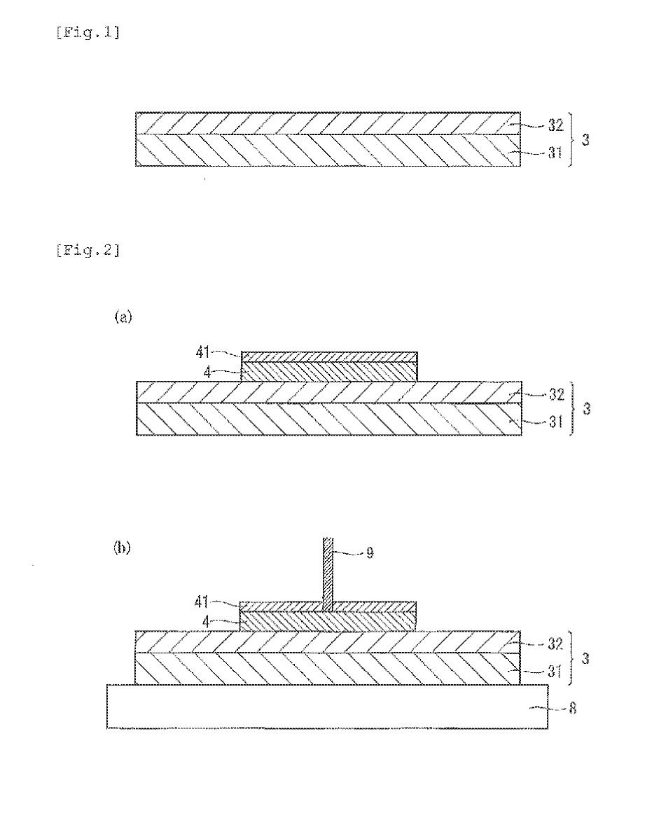

An embodiment of the present invention is explained with reference to FIG. 1. However, the present invention is not limited to this example. FIG. 1 is a cross-sectional schematic diagram showing one example of the pressure-sensitive adhesive sheet for dicing of the present invention. In the present description, parts that are not necessary for the explanation are omitted in the drawings, and there are parts in the drawings that are shown by enlarging or shrinking to make the explanation easy.

### (Pressure-Sensitive Adhesive Sheet for Dicing)

As shown in FIG. 1, a pressure-sensitive adhesive sheet 3 for dicing has a base 31 and a pressure-sensitive adhesive layer 32 provided on the base 31. The pressure-sensitive adhesive sheet 3 for dicing is only required to have a configuration in which the base 31 and the pressure-sensitive adhesive layer 32 are laminated, and may also have other layers. The base (a supporting base) can be used as a supporting base of the pressure-sensitive adhesive layer, etc.

The light transmittance at a wavelength of 355 nm of the base 31 is preferably 70% to 100%, and more preferably 80% to 95%. When the light transmittance at a wavelength of 355 nm of the base 31 is 70% to 100%, the absorption of the laser beam at the base 31 is relatively small, and damage to the base is small. As a result, tearing of the pressure-sensitive adhesive sheet 3 for dicing can be prevented upon dicing and expanding. The light transmittance at a wavelength of 355 nm of the base 31 can be measured by a method described in the Examples.

The specific heat of the base 31 is preferably 1.0 J/gK to 3.0 J/gK, and more preferably 2.0 J/gK to 3.0 J/gK. When the specific heat of the base 31 is 1.0 J/gK to 3.0 J/gK, generation of heat by laser absorption can be suppressed.

The melting point of the base 31 is preferably 90° C. or more, and more preferably 100° C. or more. The higher the melting point of the base 31 is, the better it is. However, it can be set at 300° C. or less. When the melting point of the base is 90° C. or more, melting of the base by the heat at laser processing can be prevented.

Examples of the forming material of the base 31 include polyethylene terephthalate; polyethylene naphthalate; polystyrene; polycarbonate; polyimide; a (meth)acrylic polymer; a polyurethane-based resin; a polynorbornene-based resin; a polyalkylene glycol-based resin such as polyethylene glycol or polytetramethylene glycol; a silicon-based rubber; and a polyolefin-based resin such as polyethylene, polypropylene, polybutadiene, polyvinyl alcohol, polymethylpentene, or an ethylene-vinyl acetate copolymer. However, it is not limited to these. Among these, a resin that does not contain an aromatic hydrocarbon group is preferably used, and a (meth)acrylic polymer and a polyolefin-based resin are more preferably used.

The base 31 may be single-layered or multi-layered. In the case where the base 31 is multi-layered, the intensity of laser can be weakened by light scattering between the layers and/or light refraction between the layers. The base 31 can have various forms such as a film form and a mesh form. Especially, the base 31 suitably has a form with a large porosity such as a fibrous form, a non-woven fabric, a woven fabric, or a porous body.

The thickness (total thickness when the base 31 is multi-layered) of the base 31 is not especially limited, and it is appropriately selected according to the strength, the flexibility, the purpose of use, etc. However, it is preferably 80 μm to 250 μm, more preferably 100 μm to 200 μm, and further preferably 140 μm to 160 μm. When the thickness of the base 31 is 80 μm or more, melting by laser can be suppressed. When the thickness of the base 31 is 250 μm or less, a good pickup property can be secured.

The base 31 may contain various additives such as a coloring agent, a filler, a plasticizer, an antiaging agent, an antioxidant, a surfactant, and a flame retardant as long as the effects of the present invention are not undermined.

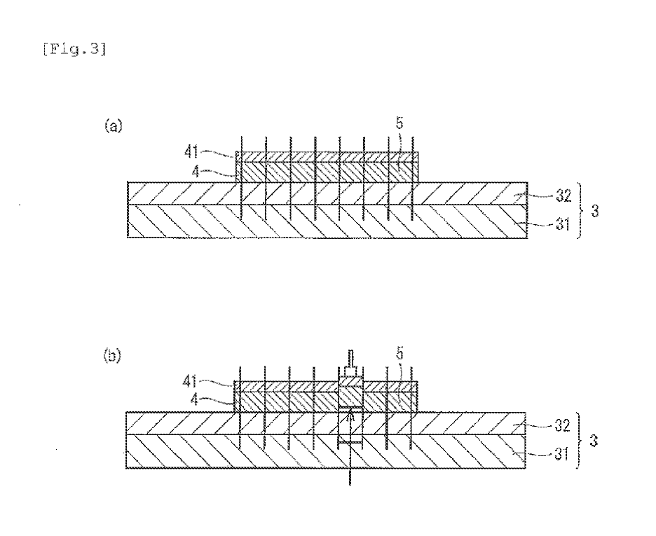

In the pressure-sensitive adhesive layer 32, 0.02 to 5 parts by weight of an ultraviolet absorber is contained with respect to 100 parts by weight of the resin solid content. The content of the ultraviolet absorber is preferably 0.1 to 1.5 parts by weight, and more preferably 0.2 to 1.0 part by weight. Because the content of the ultraviolet absorber is 0.05 part by weight or more with respect to 100 parts by weight of the resin solid content, the laser beam is absorbed by the pressure-sensitive adhesive layer 32 and the amount of the laser beam that reaches the adsorption stage can be decreased when a low dielectric material layer 41 (refer to FIG. 2(a)) that is formed on a workpiece (for example, a semiconductor wafer) is cut by light absorption ablation of the laser beam. As a result, scratching of the adsorption stage can be prevented.

Examples of the ultraviolet absorber include a benzotriazole-based ultraviolet absorber, a hydroxyphenyltriazine-based ultraviolet absorber, a benzophenone-based ultraviolet absorber, and a benzoate-based ultraviolet absorber. However, a benzotriazole-based ultraviolet absorber and/or a hydroxyphenyltriazine-based ultraviolet absorber are preferable in the present invention.

Examples of the benzotriazole-based ultraviolet absorber include 2-(2-hydroxy-5-tert-butylphenyl)-2H-benzotriazole, an ester compound of benzene propanoic acid and 3-(2H-benzotriazol-2-yl)-5-(1,1-dimethylethyl)-4-hydroxy (side chain and linear alkyl of C7 to C9), a mixture of octyl-3-[3-tert-butyl-4-hydroxy-5-(5-chloro-2H-benzotriazol-2-yl)phenyl]propionate and 2-ethylhexyl-3-[3-tert-butyl-4-hydroxy-5-(5-chloro-2H-benzo triazol-2-yl)phenyl]propionate, 2-(2H-benzotriazol-2-yl)-4,6-bis(1-methyl-1-phenylethyl)phenol, 2-(2H-benzotriazol-2-yl)-6-(1-methyl-1-phenylethyl)-4-(1,1,3,3-tetramethylbutyl)phenol, a reaction product of methyl-3-(3-(2H-benzotriazol-2-yl)-5-tert-butyl-4-hydroxyphenylpropionate and polyethylene glycol 300, 2-(2H-benzotriazol-2-yl)-p-cresol, 2-[5-chloro(2H)-benzotriazol-2-yl]-4-methyl-6-(tert-butyl)phenol, 2-(2H-benzotriazol-2-yl)-4,6-di-tert-pentylphenol, 2-(2H-benzotriazol-2-yl)-4-(1,1,3,3-tetramethylbutyl)phenol, 2-2′-methylene bis[6-(2H-benzotriazol-2-yl)-4-(1,1,3,3-tetramethylbutyl)phenol], a reaction product of methyl-3-(3-(2H-benzotriazol-2-yl)-5-tert-butyl-4-hydroxyphenyl)propionate and polyethylene glycol 300, 2-(2H-benzotriazol-2-yl)-6-dodecyl-4-methylphenol, 2-[2-hydroxy-3-(3,4,5,6-tetrahydrophthalimide-methyl)-5-methylphenyl]benzotriazole, and 2,2′-methylene bis[6-(benzotriazol-2-yl)-4-tert-octylphenol].

Examples of the hydroxyphenyltriazine-based ultraviolet absorber include a reaction product of 2-(4,6-bis(2,4-dimethylphenyl)-1,3,5-triazin-2-yl)-5-hydroxyphenyl and [(alkyloxy of C10 to C16, mainly C12 to C13)methyl]oxirane, a reaction product of 2-(2,4-dihydroxyphenyl)-4,6-bis-(2,4-dimethylphenyl)-1,3,5-triazine and (2-ethylhexyl)glycidic ester, 2,4-bis[2-hydroxy-4-butoxyphenyl]-6-(2,4-dibutoxyphenyl)-1,3,5-triazine, 2-(4,6-diphenyl-1,3,5-triazin-2-yl)-5-[(hexyl)oxy]-phenol, and 2-(2-hydroxy-4-[1-octyloxycarbonylethoxy]phenyl)-4,6-bis(4-phenylphenyl)-1,3,5-triazine.

Examples of the benzophenone-based ultraviolet absorber include 2-hydroxy-4-n-octyloxybenzophenone.

Examples of the benzoate-based ultraviolet absorber include 2,4-di-tert-butylphenyl-3,5-di-tert-butyl-4-hydroxybenzoate (TINIVIN 120).

Examples of commercially available benzotriazole-based ultraviolet absorber include “TINUVIN PS” manufactured by Ciba Japan as 2-(2-hydroxy-5-tert-butylphenyl)-2H-benzotriazole, “TINUVIN 384-2” manufactured by Ciba Japan as an ester compound of benzene propanoic acid and 3-(2H-benzotriazol-2-yl)-5-(1,1-dimethylethyl)-4-hydroxy (side chain and linear alkyl of C₇ to C₉), “TINUVIN 109” manufactured by Ciba Japan as a mixture of octyl-3-[3-tert-butyl-4-hydroxy-5-(5-chloro-2H-benzotriazol-2-yl)phenyl]propionate and 2-ethylhexyl-3-[3-tert-butyl-4-hydroxy-5-(5-chloro-2H-benzo triazol-2-yl)phenyl]propionate, “TINUVIN 900” manufactured by Ciba Japan as 2-(2H-benzotriazol-2-yl)-4,6-bis(1-methyl-1-phenylethyl)phenol, “TINUVIN 928” manufactured by Ciba Japan as 2-(2H-benzotriazol-2-yl)-6-(1-methyl-1-phenylethyl)-4-(1,1,3,3-tetramethylbutyl)phenol, “TINUVIN 1130” manufactured by Ciba Japan as a reaction product of methyl-3-(3-(2H-benzotriazol-2-yl)-5-tert-butyl-4-hydroxyphenyl)propionate and polyethylene glycol 300, “TINUVIN P” manufactured by Ciba Japan as 2-(2H-benzotriazol-2-yl)-p-cresol, “TINUVIN 326” manufactured by Ciba Japan as 2-[5-chloro(2H)-benzotriazol-2-yl]-4-methyl-6-(tert-butyl)phenol, “TINUVIN 328” manufactured by Ciba Japan as 2-(2H-benzotriazol-2-yl)-4,6-di-tert-pentylphenol, “TINUVIN 329” manufactured by Ciba Japan as 2-(2H-benzotriazol-2-yl)-4-(1,1,3,3-tetramethylbutyl)phenol, “TINUVIN 360” manufactured by Ciba Japan as 2-2′-methylene bis[6-(2H-benzotriazol-2-yl)-4-(1,1,3,3-tetramethylbutyl)phenol], “TINUVIN 213” manufactured by Ciba Japan as a reaction product of methyl-3-(3-(2H-benzotriazol-2-yl)-5-tert-butyl-4-hydroxyphenyl)propionate and polyethylene glycol 300, “TINUVIN 571” manufactured by Ciba Japan as 2-(2H-benzotriazol-2-yl)-6-dodecyl-4-methylphenol, “Sumisorb 250” manufactured by Sumitomo Chemical Co., Ltd. as 2-[2-hydroxy-3-(3,4,5,6-tetrahydrophthalimide-methyl)-5-methylphenyl]benzotriazole, and “ADKSTAB LA31” manufactured by ADEKA Corporation as 2,2′-methylene bis[6-(benzotriazol-2-yl)-4-tert-octylphenol].

Examples of commercially available hydroxyphenyltriazine-based ultraviolet absorber include “TINUVIN 400” manufactured by Ciba Japan as a reaction product of 2-(4,6-bis(2,4-dimethylphenyl)-1,3,5-triazin-2-yl)-5-hydroxyphenyl and [(alkyloxy of C10 to C16, mainly C12 to C13)methyl]oxirane, “TINUVIN 405” manufactured by Ciba Japan as a reaction product of 2-(2,4-dihydroxyphenyl)-4,6-bis-(2,4-dimethylphenyl)-1,3,5-triazine and (2-ethylhexyl)glycidic ester, “TINUBIN 460” manufactured by Ciba Japan as 2,4-bis[2-hydroxy-4-butoxyphenyl]-6-(2,4-dibutoxyphenyl)-1,3,5-triazine, “TINUVIN 1577” manufactured by Ciba Japan as 2-(4,6-diphenyl-1,3,5-triazin-2-yl)-5-[(hexyl)oxy]-phenol, and “TINUVIN 479” manufactured by Ciba Japan as 2-(2-hydroxy-4-[1-octyloxycarbonylethoxy]phenyl)-4,6-bis(4-phenylphenyl)-1,3,5-triazine.

Examples of commercially available benzoate-based ultraviolet absorber include “TINIVIN 120” manufactured by Ciba Japan as 2,4-di-tert-butylphenyl-3,5-di-tert-butyl-4-hydroxybenzoate.

In the present invention, the ultraviolet absorber may be used either alone or in combination of two or more of them.

A pressure-sensitive adhesive containing a (meth)acrylic polymer, a rubber-based polymer, etc. can be used as a forming material of the pressure-sensitive adhesive layer 32.

Examples of the monomer component forming the (meth)acrylic polymer are alkyl(meth)acrylates having a linear or a branched alkyl group having 30 or less carbon number, preferably 3 to 18 carbon number, such as a methyl group, an ethyl group, an n-propyl group, an isopropyl group, an n-butyl group, a t-butyl group, an isobutyl group, an amyl group, an isoamyl group, a hexyl group, a heptyl group, a cyclohexyl group, a 2-ethylhexyl group, an octyl group, an isooctyl group, a nonyl group, an isononyl group, a decyl group, an isodecyl group, an undecyl group, a lauryl group, a tridecyl group, a tetradecyl group, a stearyl group, an octadecyl group, and a dodecyl group. These alkyl(meth)acrylates may be used alone, or two or more of them may be used.

Examples of the monomer component other than the above include a carboxyl group-containing monomer such as acrylic acid, methacrylic acid, carboxyethyl(meth)acrylate, carboxypentyl(meth)acrylate, itaconic acid, maleic acid, fumaric acid, and crotonic acid, an acid anhydride monomer such as maleic anhydride and itaconic anhydride, a hydroxyl group-containing monomer such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxymethylcyclohexyl)methyl(meth)acrylate, a sulfonic acid group-containing monomer such as allylsulfonic acid, 2-(meth)acrylamide-2-methylpropanesulfonic acid, (meth)acrylamidepropanesulfonic acid, and sulfopropyl(meth)acrylate, and a phosphate group-containing monomer such as 2-hydroxyethylacryloylphosphate. These monomer components may be used alone, or two or more of them may be used.

Further, a multifunctional monomer and the like may be used as a copolymerization monomer component as needed for the purpose of a crosslinking treatment or the like of the (meth)acrylic polymer.

Examples of the multifunctional monomer include hexanediol di(meth)acrylate, (poly)ethylene glycol di(meth)acrylate, (poly)propylene glycol di(meth)acrylate, neopentyl glycol di(meth)acrylate, pentaerythritol di(meth)acrylate, trimethylolpropane tri(meth)acrylate, tetramethylolmethane tetra(meth)acrylate, pentaerythritol tri(meth)acrylate, pentaerythritol tetra(meth)acrylate, dipentaerythritol monohydroxy penta(meth)acrylate, dipentaerythritol hexa(meth)acrylate, epoxy(meth)acrylate, polyester(meth)acrylate, and urethane(meth)acrylate. These multifunctional monomers may be used alone, or two or more of them may be used.

The amount used of the multifunctional monomer is preferably 30% by weight or less of all the monomer components from the viewpoint of, e.g., adhesive characteristics, and more preferably 20% by weight or less.

Preparation of the (meth)acrylic polymer can be performed by adopting an appropriate method such as a solution polymerization method, an emulsion polymerization method, a bulk polymerization method, or a suspension polymerization method on a mixture containing one type or two types or more of the monomer components.

Exemplary polymerization initiators include a peroxide based initiator such as hydrogen peroxide, benzoyl peroxide, and t-butyl peroxide. The polymerization initiator is preferably used alone, but it can be used as a redox system polymerization initiator in combination with a reducing agent. Exemplary reducing agents include an ionized salt such as sulfite, bisulfite, iron salt, copper salt, and cobalt salt, amines such as triethanolamine, and a reducing sugar such as aldose and ketose. Further, an azo compound is also a preferred polymerization initiator, and 2,2′-azobis-2-methylpropioamidinate, 2,2′-azobis-2,4-dimethylvaleronitrile, 2,2′-azobis-N,N′-dimethyleneisobutylamidinate, 2,2′-azobisisobutylonitrile, and 2,2′-azobis-2-methyl-N-(2-hydroxyethyl)propionamide, or the like may be used. Further, two types or more of the above-described polymerization initiator can be also used.

The reaction temperature is normally about 50 to 85° C., and the reaction time is about 1 to 8 hours. Further, among the above-mentioned manufacturing methods, the solution polymerization method is preferred, and a polar solvent such as ethyl acetate and toluene is generally used as a solvent of the (meth)acrylic polymer. The solution concentration is normally about 20 to 80% by weight.

A crosslinking agent may be appropriately added to the pressure-sensitive adhesive to increase the number average molecular weight of the (meth)acrylic polymer as the base polymer. Examples of the crosslinking agent include a polyisocyanate compound, an epoxy compound, an aziridine compound, a urea resin, an anhydrous compound, a polyamine, and a carboxyl group-containing polymer. In the case of using the crosslinking agent, the amount used thereof is preferably about 0.01 to 5 parts by weight with respect to 100 parts by weight of the base polymer, considering that the adhesive strength for peeling off does not become too low. Further, various additives such as an ultraviolet absorber, an antioxidant, a tackifier, an antiaging agent, a filler, and a coloring agent may be contained in the pressure-sensitive adhesive that forms the pressure-sensitive adhesive layer besides the above-described components as needed.

In order to improve the peeling property from the workpiece, the pressure-sensitive adhesive may be a radiation curing type pressure-sensitive adhesive that is cured by radiation such as ultraviolet rays and electron beams. In the case of using a radiation curing type pressure-sensitive adhesive as the pressure-sensitive adhesive, a base with a sufficient radiation transmitting property is preferable because the pressure-sensitive adhesive layer is irradiated with radiation after laser processing.

The radiation curing type pressure-sensitive adhesive having a radiation curable functional group such as a carbon-carbon double bond and that exhibits adherability can be used without particular limitation. Exemplary radiation curing type pressure-sensitive adhesives include a radiation curing type pressure-sensitive adhesive in which a radiation curable monomer component and oligomer component are included in the above-described (meth)acrylic polymer.

Exemplary compounding radiation curable monomer components and oligomer components include urethane(meth)acrylate, trimethylolpropane tri(meth)acrylate, tetramethylolmethane tetra(meth)acrylate, pentaerythritol tri(meth)acrylate, pentaerythritol tetra(meth)acrylate, dipentaerythritol monohydroxy penta(meth)acrylate, dipentaerythiritolhexa(meth)acrylate, and 1,4-butyleneglycol di(meth)acrylate. These may be used alone, or two or more types may be used.

The compounding amount of the radiation curable monomer component and oligomer component is not particularly limited. However, it is preferably about 5 to 500 parts by weight with respect to the base polymer 100 parts by weight of, e.g., the (meth)acrylic polymer constituting the pressure-sensitive adhesive considering adherability, and more preferably about 70 to 150 parts by weight.

Further, in the radiation curing type pressure-sensitive adhesive, a polymer having a carbon-carbon double bond in a polymer side-chain, in a main chain, or at the end of the main chain can be used as the base polymer. Such a base polymer preferably has a (meth)acrylic polymer as a basic skeleton. In this case, the radiation curable monomer component and oligomer component do not have to be added and they are optionally used.

A photopolymerization initiator is contained in the radiation curing type pressure-sensitive adhesive in the case of curing using ultraviolet rays, and the like. Examples of the photopolymerization initiator include camphorquinone, halogenated ketones, acylphosphine oxide, and acylphosphonate.

The compounding amount of the photopolymerization initiator is preferably about 0.1 to 10 parts by weight, and more preferably about 0.5 to 5 parts by weight with respect to 100 parts by weight of the base polymer, e.g., the (meth)acrylic polymer constituting the pressure-sensitive adhesive.

The pressure-sensitive adhesive layer 32 can be formed by a widely-used method of mixing the pressure-sensitive adhesive with a solvent, other additives, and the like as needed to form a sheet layer. Specific examples of the method of forming the pressure-sensitive adhesive layer 32 include a method of applying a mixture containing the pressure-sensitive adhesive and a solvent and other additives as needed onto the base 31 and a method of applying the mixture onto an appropriate separator such as release paper to form the pressure-sensitive adhesive layer 32 and transferring the layer 32 onto the base 31.

The thickness of the pressure-sensitive adhesive layer 32 is not especially limited. However, it is 3 μm to 50 μm, preferably 5 μm to 30 μm, and more preferably 7 μm to 20 μm. When the thickness of the pressure-sensitive adhesive layer 32 is within the above-described range, a moderate adhesive strength can be exhibited. The pressure-sensitive adhesive layer 32 may be single-layered or multi-layered.

The thickness of the pressure-sensitive adhesive sheet 3 for dicing can be selected from a range of 80 μm to 300 μm for example, and is preferably 100 μm to 200 μm, and more preferably 150 μm to 170 μm.

### (Method of Manufacturing Pressure-Sensitive Adhesive Sheet for Dicing)

The method of manufacturing a pressure-sensitive adhesive sheet for dicing according to the present embodiment is explained using a film 1 for a back side of a semiconductor integrated with a pressure-sensitive adhesive sheet for dicing shown in FIG. 1 as an example. First, the base 31 can be formed by a conventionally known film forming method. Examples of the film forming method include a calender film forming method, a casting method in an organic solvent, an inflation extrusion method in a closed system, a T-die extrusion method, a co-extrusion method, and a dry lamination method.

Next, the pressure-sensitive adhesive composition is applied to the base 31 and dried (heated and crosslinked as needed) to form the pressure-sensitive adhesive layer 32. Examples of the application method include a roll coating method, a screen coating method, and a gravure coating method. The pressure-sensitive adhesive layer composition may be directly applied to the base 31 to form the pressure-sensitive adhesive layer 32 on the base 31. Alternatively, the pressure-sensitive adhesive composition may be applied to release paper or the like subjected to a release treatment to form the pressure-sensitive adhesive layer 32 and then the pressure-sensitive adhesive layer 32 may be transferred to the base 31. With this operation, the pressure-sensitive adhesive sheet 3 for dicing can be produced in which the pressure-sensitive adhesive layer 32 is formed on the base 31.

Here, a semiconductor wafer having a low dielectric material layer formed is explained. The low dielectric material layer 41 is formed on a front side (the circuit surface) of a semiconductor wafer 4 (refer to FIGS. 2(a) and 2(b)).

The semiconductor wafer 4 is not especially limited as long as it is a known or widely-used semiconductor wafer, and can be appropriately selected for use from semiconductor wafers of various materials. In the present invention, a silicon wafer can be suitably used as a semiconductor wafer. A semiconductor wafer having a thickness of 10 μm to 800 μm can be used as the semiconductor wafer 4, for example. Especially, a semiconductor wafer having a thickness of 20 μm to 200 μm can be used.

The low dielectric material layer 41 can be formed using a material having a low dielectric constant, a so-called low-k material. Examples thereof include a SiO₂ film (dielectric constant k=4.2), a SiOF film (k=3.5 to 3.7), and a SiOC film (k=2.5 to 2.8). The low dielectric material layer 41 can be formed on a semiconductor wafer 2 by a plasma CVD method or the like.

### (Method of Manufacturing Semiconductor Device)

The method of manufacturing a semiconductor device according to the present embodiment is explained below with reference to FIGS. 2 and 3. FIGS. 2 and 3 are cross-sectional schematic diagrams showing a method of manufacturing a semiconductor device using the pressure-sensitive adhesive sheet 3 for dicing.

In the method of manufacturing a semiconductor device, a semiconductor device can be manufactured by using the pressure-sensitive adhesive sheet 3 for dicing. Specifically, the method includes a step of applying the pressure-sensitive adhesive sheet 3 for dicing to a back side of the semiconductor wafer 4 in which the low dielectric material layer 41 is formed on a front side, and a laser scribing step of irradiating the front side of the semiconductor wafer 4 with an ultraviolet ray laser beam to cut the low dielectric material layer 41.

### [Mounting Step]

First, as shown in FIG. 2(a), a separator that is optionally provided on the pressure-sensitive adhesive sheet 3 for dicing is appropriately peeled, the semiconductor wafer 4 with the low dielectric material layer 41 is applied to the pressure-sensitive adhesive layer 32, and the wafer 4 is adhered and held (a mounting step). The pressure-sensitive adhesive sheet 3 for dicing is applied to a back side of the semiconductor wafer 4. The back side of the semiconductor wafer 4 means the surface on the other side of the circuit surface (also called as a non-circuit surface, a non-electrode-formed surface, etc.). The application method is not especially limited. However, a method of pressure bonding is preferable. The pressure bonding is normally performed under pressing with a pressing means such as a pressing roll.

### [Laser Scribing Step]

Then, the low dielectric material layer 41 is cut using a laser beam as shown in FIG. 2(b). The cutting of the low dielectric material layer 41 is performed while the semiconductor wafer 4 to which the pressure-sensitive adhesive sheet 3 for dicing is applied to is adsorbed by an adsorption stage 8. At this time, because the pressure-sensitive adhesive sheet 3 for dicing is used having the pressure-sensitive adhesive layer 31 in which 0.05 to 2 parts by weight of an ultraviolet absorber is contained with respect to 100 parts by weight of the resin solid content and in which the light transmittance at a wavelength of 355 nm is 30% to 80%, the laser beam is absorbed by the pressure-sensitive adhesive layer 32 and the amount of the laser beam that reaches the adsorption stage can be decreased. As a result, scratching of the adsorption stage can be prevented.

As a laser 9 to cut the low dielectric material layer 41, a laser can be used that is capable of an ablation processing by ultraviolet ray absorption that is a non-heat processing without a heat processing.

The reasons include (1) carbon residue is hardly generated because it is a photo (degradation) reaction, (2) the processing can be performed on many types of adherends such as metals, glass, organic materials, and ceramics, and (3) the processed surface becomes sharper than that in the heat processing by infrared absorption because it is a local heat reaction.

Specific examples of the laser include a laser having an oscillation wavelength of 400 nm or less such as a KrF excimer laser having an oscillation wavelength of 248 nm, a XeCl excimer laser of 308 nm, a third harmonic (355 nm) and a fourth harmonic (266 nm) of a YAG laser, and a laser having an oscillation wavelength of 400 nm or more such as a titanium sapphire laser of a wavelength near 750 nm to 800 nm that is capable of light absorption in an ultraviolet region through a multiphoton absorption process and a cutting processing of a width of 20 μm or less by multiphoton absorption ablation having a pulse width of 1 e⁻⁹ sec (0.000000001 sec) or less. Especially preferable is a laser for which the laser beam can be concentrated to a narrow width of 20 μm or less and that radiates an ultraviolet ray of 355 nm.

For example, as the laser beam irradiation conditions in this laser scribing step, a third harmonic (355 nm) of a YAG laser having a wavelength of 355 nm, an average output of 0.1 W to 10 W, and a repetition frequency of 1 kHz to 50 kHz is concentrated to a beam of 10 μm to 100 μm in diameter with an objective lens (fθ lens), and the scanning of the laser beam is performed by a galvanoscanner at a speed of 1 mm/sec to 100 mm/sec.

### [Dicing Step]

Next, dicing of the semiconductor wafer 4 is performed as shown in FIG. 3(a). With this operation, the semiconductor wafer 4 is cut into individual pieces of a prescribed size (made into small pieces) to manufacture a semiconductor chip 5. The dicing is performed using, for example, a dicing blade from the circuit surface side of the semiconductor wafer 4. In this step, a cutting method so-called fullcut can be adopted, in which the cutting is performed to the pressure-sensitive adhesive sheet 3 for dicing. The dicing apparatus used in this step is not particularly limited, and a conventionally known apparatus may be used. Because the semiconductor wafer 4 is adhered and fixed with excellent adhesion by the pressure-sensitive adhesive sheet 3 for dicing, damage of the semiconductor wafer 4 can be suppressed together with the suppression of chipping of the chip and chip fly.

When expansion of the pressure-sensitive adhesive sheet 3 for dicing is performed, a conventionally known expansion apparatus can be used. The expansion apparatus has a donut-shaped outer ring that can push down the pressure-sensitive adhesive sheet 3 for dicing through a dicing ring and an inner ring having a smaller diameter than that of the outer ring and that supports the pressure-sensitive adhesive sheet 3 for dicing. With this expansion step, damage caused by the contact between adjacent semiconductor chips can be prevented in the pickup step described later.

### EXAMPLES

The present invention is explained below in detail with reference to examples. However, the present invention is not limited to the following examples as long as it does not deviate from its purpose. In the Examples, “part(s)” is on the weight basis as long as there is no special mention otherwise.

### (Measurement of Specific Heat of Base)

The specific heat of the base used in the examples and comparative examples was measured as follows.

### [Measurement of Specific Heat]

The specific heat of the base was measured using a heat analysis system (DSC EXSTAR 6000 manufactured by Seiko Instruments Inc.). The measurement was performed at a temperature rise rate of 10° C./min, and three DSC curves of an empty container, a sample, and a reference (water) were obtained.

Then, the specific heat was obtained by the following formula.

Cps=(Ys/Yr)×(Mr/Ms)×Cpr

Cps: Specific heat of sample

Cpr: Specific heat of reference (water: 4.2 J/(gK))

Ys: Difference of DSC curves between sample and empty container

Yr: Difference of DSC curves between reference and empty container

Ms: Mass of sample

Mr: Mass of reference

### (Measurement of Melting Point of Base)

The melting point of the base used in the following examples and comparative examples was measured at a temperature rise condition of 5° C./min using DSCQ2000 manufactured by TA Instruments.

### Example 1

### Base

A film (trade name: TORAYFAN B02500 manufactured by TORAY Industries, Inc.) having a thickness of 100 μm and made of PP (polypropylene) was prepared. The specific heat of this base was 1.31 J/gK, and the melting point was 140° C.

### <Pressure-Sensitive Adhesive Sheet for Dicing>

An acrylic pressure-sensitive adhesive solution (A) was applied to the base and dried to form a pressure-sensitive adhesive layer, and thus a pressure-sensitive adhesive sheet for dicing according to Example 1 was obtained. The thickness of the pressure-sensitive adhesive layer was 10 μm. The acrylic pressure-sensitive adhesive solution (A) was prepared by the following method.

### <Acrylic Pressure-Sensitive Adhesive Solution (A)>

100 parts by weight of a copolymer (solid content 20%) having a weight average molecular weight of 900,000 that was obtained by copolymerizing 100 parts by weight of butyl acrylate and 5 parts by weight of acrylic acid, 2 parts by weight of an isocyanate-based crosslinking agent (trade name: “Coronate L” manufactured by Nippon Polyurethane Industry Co., Ltd.) as the crosslinking agent, 1 part by weight of an epoxy-based crosslinking agent (trade name: “TETRAD C” manufactured by Mitsubishi Gas Chemical Company, Inc.), and 0.25 part by weight of an ultraviolet absorber (TINUVIN 326 manufactured by BASF SE) were added in toluene, and were uniformly dissolved and mixed to prepare the acrylic pressure-sensitive adhesive solution (A).

### Example 2

### Base

A film (trade name: Opulent X-88 manufactured by Mitsui Chemicals, Inc.) having a thickness of 100 μm and made of PMP (polymethylpentene) was prepared. The specific heat of this base was 1.34 J/gK, and the melting point was 223° C.

### <Pressure-Sensitive Adhesive Sheet for Dicing>

An acrylic pressure-sensitive adhesive solution (A) was applied to the base and dried to form a pressure-sensitive adhesive layer, and thus a pressure-sensitive adhesive sheet for dicing according to Example 2 was obtained. The thickness of the pressure-sensitive adhesive layer was 10 μm.

### Example 3

### Base

A film having a thickness of 15 μm and made of PE (polyethylene), a film having a thickness of 60 μm and made of PP (polypropylene), and a film having a thickness of 15 μm and made of PE (polyethylene) were laminated in this order to prepare a film (total thickness 90 μm). Specifically, a low density polyethylene (PE) (F522N manufactured by Ube Industries, Ltd.) was melted using two extruders so that it could be an inner layer (A) and an outer layer (A), and a composition (CAP 355 manufactured by Ube Industries, Ltd.) of amorphous polyolefin and crystalline polypropylene (PP) was melted using another extruder so that it could be an intermediate layer (B). The three layers were fused to each other and laminated in a T-die at 250° C. in the order of (A)/(B)/(A), and the laminate was extruded out of the T-die. The laminate was withdrawn at a draw ratio of 2.5 using a draw-off roll (the surface of the roll is 6s satin-finished) with an air knife in which warm water of 70° C. was let through the inside to obtain a film having a total thickness of 90 μm having an inner layer (A) and an outer layer (A) of both 15 μm and an intermediate layer (B) of 60 μm.

The melting point of the film made of PE (polyethylene) was 100° C., and the melting point of the film made of PP (polypropylene) was 140° C. The specific heat of the laminated film was 1.69 J/gK.

### <Pressure-Sensitive Adhesive Sheet for Dicing>

An acrylic pressure-sensitive adhesive solution (B) was applied to the base and dried to form a pressure-sensitive adhesive layer, and thus a pressure-sensitive adhesive sheet for dicing according to Example 3 was obtained. The thickness of the pressure-sensitive adhesive layer was 10 μm. The acrylic pressure-sensitive adhesive solution (B) was prepared by the following method.

### <Acrylic Pressure-Sensitive Adhesive Solution (B)>

An acrylic pressure-sensitive adhesive solution (B) was prepared by the same method as that for the acrylic pressure-sensitive adhesive solution (A) except that the added amount of the ultraviolet absorber was changed to 0.85 part by weight.

### Example 4

### Base

A film having a thickness of 30 μm and made of PE (polyethylene), a film having a thickness of 90 μm and made of PP (polypropylene), and a film having a thickness of 30 μm and made of PE (polyethylene) were laminated in this order to prepare a film (total thickness 150 μm). The melting point of the film made of PE (polyethylene) was 100° C., and the melting point of the film made of PP (polypropylene) was 140° C. The specific heat of the laminated film was 1.69 J/gK.

### <Pressure-Sensitive Adhesive Sheet for Dicing>

An acrylic pressure-sensitive adhesive solution (C) was applied to the base and dried to form a pressure-sensitive adhesive layer, and thus a pressure-sensitive adhesive sheet for dicing according to Example 4 was obtained. The thickness of the pressure-sensitive adhesive layer was 10 μm. The acrylic pressure-sensitive adhesive solution (C) was prepared by the following method.

### <Acrylic Pressure-Sensitive Adhesive Solution (C)>

An acrylic pressure-sensitive adhesive solution (C) was prepared by the same method as that for the acrylic pressure-sensitive adhesive solution (A) except that the added amount of the ultraviolet absorber was changed to 0.6 part by weight.

### Example 5

### Base

A film in which a film having a thickness of 30 μm and made of PE (polyethylene), a film having a thickness of 90 μm and made of PP (polypropylene), and a film having a thickness of 30 μm and made of PE (polyethylene) are laminated in this order (manufactured by Nitta Denko Corporation, total thickness 150 μm) was prepared. The melting point of the film made of PE (polyethylene) was 100° C., and the melting point of the film made of PP (polypropylene) was 140° C. The specific heat of the laminated film was 1.69 J/gK.

### <Pressure-Sensitive Adhesive Sheet for Dicing>

An acrylic pressure-sensitive adhesive solution (A) was applied to the base and dried to form a pressure-sensitive adhesive layer, and thus a pressure-sensitive adhesive sheet for dicing according to Example 5 was obtained. The thickness of the pressure-sensitive adhesive layer was 10 μm.

### Comparative Example 1

### Base

A film having a thickness of 145 μm and made of PVC (polyvinyl chloride) was produced by calender rolling of a common method. The specific heat of this base was 1.5 J/gK, and the melting point was 170° C.

### <Pressure-Sensitive Adhesive Sheet for Dicing>

An acrylic pressure-sensitive adhesive solution (C) was applied to the base and dried to form a pressure-sensitive adhesive layer, and thus a pressure-sensitive adhesive sheet for dicing according to Comparative Example 1 was obtained. The thickness of the pressure-sensitive adhesive layer was 10 μm.

### Comparative Example 2

### Base

A film (trade name: NHAA manufactured by Achilles Corporation) having a thickness of 100 μm and made of PVC (polyvinyl chloride) was prepared. The specific heat of this base was 1.5 J/gK, and the melting point was 170° C.

### <Pressure-Sensitive Adhesive Sheet for Dicing>

An acrylic pressure-sensitive adhesive solution (D) was applied to the base and dried to form a pressure-sensitive adhesive layer, and thus a pressure-sensitive adhesive sheet for dicing according to Comparative Example 2 was obtained. The thickness of the pressure-sensitive adhesive layer was 10 μm. The acrylic pressure-sensitive adhesive solution (D) was prepared by the following method.

### <Acrylic Pressure-Sensitive Adhesive Solution (D)>

An acrylic pressure-sensitive adhesive solution (D) was prepared by the same method as that for the acrylic pressure-sensitive adhesive solution (A) except that no ultraviolet absorber was added.

### Comparative Example 3

### Base

A film having a thickness of 30 μm and made of PE (polyethylene), a film having a thickness of 90 μm and made of PP (polypropylene), and a film having a thickness of 30 μm and made of PE (polyethylene) were laminated in this order to prepare a film (total thickness 150 μm). The melting point of the film made of PE (polyethylene) was 100° C., and the melting point of the film made of PP (polypropylene) was 140° C. The specific heat of the laminated film was 1.69 J/gK.

### <Pressure-Sensitive Adhesive Sheet for Dicing>

An acrylic pressure-sensitive adhesive solution (D) was applied to the base and dried to form a pressure-sensitive adhesive layer, and thus a pressure-sensitive adhesive sheet for dicing according to Comparative Example 3 was obtained. The thickness of the pressure-sensitive adhesive layer was 10 μm.

### Comparative Example 4

### Base

A film having a thickness of 30 μm and made of PE (polyethylene), a film having a thickness of 90 μm and made of PP (polypropylene), and a film having a thickness of 30 μm and made of PE (polyethylene) were laminated in this order to prepare a film (total thickness 150 μm). The melting point of the film made of PE (polyethylene) was 100° C., and the melting point of the film made of PP (polypropylene) was 140° C. The specific heat of the laminated film was 1.69 J/gK.

### <Pressure-Sensitive Adhesive Sheet for Dicing>

An acrylic pressure-sensitive adhesive solution (E) was applied to the base and dried to form a pressure-sensitive adhesive layer, and thus a pressure-sensitive adhesive sheet for dicing according to Comparative Example 4 was obtained. The thickness of the pressure-sensitive adhesive layer was 10 μm. The acrylic pressure-sensitive adhesive solution (E) was prepared by the following method.

### <Acrylic Pressure-Sensitive Adhesive Solution (E)>

An acrylic pressure-sensitive adhesive solution (E) was prepared by the same method as that for the acrylic pressure-sensitive adhesive solution (A) except that the added amount of the ultraviolet absorber was changed to 0.96 part by weight.

### Comparative Example 5

### Base

A film (trade name: Teonex Q83 manufactured by Teijin DuPont Films Japan Limited) having a thickness of 100 μm and made of PEN (polyethylene naphthalate) was prepared. The specific heat of the base was 0.87 J/gK, and the melting point was 255° C.

### <Pressure-Sensitive Adhesive Sheet for Dicing>

An acrylic pressure-sensitive adhesive solution (D) was applied to the base and dried to form a pressure-sensitive adhesive layer, and thus a pressure-sensitive adhesive sheet for dicing according to Comparative Example 5 was obtained. The thickness of the pressure-sensitive adhesive layer was 10 μm.

### (Measurement of Light Transmittance at Wavelength of 355 nm of Base and Pressure-Sensitive Adhesive Sheet for Dicing)

The light transmittance at a wavelength of 355 nm was measured for the bases that were used in the examples and comparative examples. The light transmittance at a wavelength of 355 nm was measured for the pressure-sensitive adhesive sheets for dicing according to the examples and comparative examples. In the measurement, a UV-VIS spectrophotometer UV-2550 manufactured by Shimadzu Corporation was used.

The results are shown in Table 1.

### (Evaluation of Tearing of Base and Damage of Processing Table)

The evaluation of tearing of the base and damage of a processing table was performed as follows.

First, the pressure-sensitive adhesive sheet for dicing was set on a silicon wafer. Next, a third harmonic (355 nm) of a YAG laser having a wavelength of 355 nm, an average output of 0.75 W, and a repetition frequency of 5 kHz was concentrated to a beam of 30 μm in diameter with an objective lens (fθ lens), and the scanning was performed three times with a galvanoscanner at a speed of 15 mm/sec. The focal point was 500 μm upwards from the pressure-sensitive adhesive layer. Then, whether there was tearing of the base of the pressure-sensitive adhesive sheet for dicing or not was confirmed visually and by an optical microscope. The results are shown in Table 1. Next, the pressure-sensitive adhesive sheet for dicing was removed from the silicon wafer, and whether there were laser scars or not was confirmed visually. The results are shown in Table 1.

TABLE 1

| | Example 1 | Example 2 | Example 3 | Example 4 | Example 5 |
|---|---|---|---|---|---|
| Material of Base | PP | PMP | PE/PP/PE | PE/PP/PE | PE/PP/PE |
| Base Thickness (μm) | 100 | 100 | 90 | 150 | 150 |
| Light Transmittance at | 90% | 75% | 85% | 85% | 85% |
| 355 nm of Base | | | | | |
| Thickness (μm) of Pressure- | 10 | 10 | 10 | 10 | 10 |
| Sensitive Adhesive Layer | | | | | |
| Added Amount (part by | 0.25 | 0.25 | 0.85 | 0.6 | 0.25 |
| weight) of Ultraviolet | | | | | |
| Absorber to Pressure- | | | | | |
| Sensitive Adhesive | | | | | |
| Light Transmittance at | 70% | 42% | 30% | 47% | 75% |
| 355 nm of Pressure-Sensitive | | | | | |
| Adhesive Sheet for Dicing | | | | | |
| Tearing of Base | None | None | None | None | None |
| Damage of Adsorption Stage | None | None | None | None | None |
| | Comparative | Comparative | Comparative | Comparative | Comparative |
| | Example 1 | Example 2 | Example 3 | Example 4 | Example 5 |
| Material of Base | PVC | PVC | PE/PP/PE | PE/PP/PE | PEN |
| Base Thickness (μm) | 145 | 80 | 150 | 150 | 100 |
| Light Transmittance at | 25% | 45% | 85% | 85% | 3% |
| 355 nm of Base | | | | | |
| Thickness (μm) of Pressure- | 10 | 10 | 10 | 10 | 10 |
| Sensitive Adhesive Layer | | | | | |
| Added Amount (part by | 0.6 | 0 | 0 | 0.96 | 0.6 |
| weight) of Ultraviolet | | | | | |
| Absorber to Pressure- | | | | | |
| Sensitive Adhesive | | | | | |
| Light Transmittance at | 19% | 37% | 89% | 20% | 1% |
| 355 nm of Pressure-Sensitive | | | | | |
| Adhesive Sheet for Dicing | | | | | |
| Tearing of Base | Yes | Yes | None | Yes | Yes |
| Damage of Adsorption Stage | Yes | Yes | Yes | Yes | Yes |

### DESCRIPTION OF THE REFERENCE NUMERALS

3 Pressure-Sensitive Adhesive Sheet for Dicing
31 Base
32 Pressure-Sensitive Adhesive Layer
4 Semiconductor Wafer
41 Low Dielectric Material Layer
5 Semiconductor Chip
8 Adsorption Stage
9 Laser Beam

1. A pressure-sensitive adhesive sheet for dicing having a base and a pressure-sensitive adhesive layer provided on the base, wherein
0.02 to 5 parts by weight of an ultraviolet absorber is contained in the pressure-sensitive adhesive layer with respect to 100 parts by weight of resin solid content, and
the light transmittance at a wavelength of 355 nm of the pressure-sensitive adhesive sheet for dicing is 30% to 80%.

2. The pressure-sensitive adhesive sheet for dicing according to claim 1, wherein the light transmittance at a wavelength of 355 nm of the base is 70% to 100%.

3. The pressure-sensitive adhesive sheet for dicing according to claim 1, wherein the base is multi-layered.

4. The pressure-sensitive adhesive sheet for dicing according to claim 1, wherein the specific heat of the base is 1.0 J/gK to 3.0 J/gK.

5. The pressure-sensitive adhesive sheet for dicing according to claim 1, wherein the melting point of the base is 90° C. or more.

6. A method of manufacturing a semiconductor device comprising:
a step of applying the pressure-sensitive adhesive sheet for dicing according to any one of claims 1 to 5 to a back side of a semiconductor wafer in which a low dielectric material layer is formed on a front side; and
a laser scribing step of irradiating the front side of the semiconductor wafer with an ultraviolet ray laser beam to cut the low dielectric material layer.
